(19) United States
(12) Patent Application Publication
(10) Pub. No.: US 2019/0204748 A1
(43) Pub. Date: Jul. 4, 2019

(54) METHOD FOR REMOVING PATTERNED NEGATIVE PHOTORESIST

(71) Applicants: UNITED MICROELECTRONICS CORP., Hsin-Chu City (TW); Fujian Jinhua Integrated Circuit Co., Ltd., Quanzhou City (CN)

(72) Inventors: Feng-Ming Huang, Pingtung County (TW); Chien-Cheng Tsai, Kaohsiung City (TW)

(21) Appl. No.: 15/872,912

(22) Filed: Jan. 16, 2018

(30) Foreign Application Priority Data
Jan. 3, 2018 (CN) 201810004020.4

(51) Int. Cl. G03F 7/42; H01L 21/311

(52) U.S. Cl. CPC G03F 7/427; H01L 21/31138

(57) ABSTRACT

A method for removing a patterned negative photoresist from a substrate includes: (a) placing the substrate on lift pins of a wafer chuck; (b) retracting the lift pins to place the substrate in a pin-down position and concurrently heating the substrate to a first temperature not exceeding 100° C.; (c) raising the lift pins to place the substrate in a pin-up position; (d) generating a plasma from a gas comprising NH₃; and (e) exposing the substrate to the plasma in the pin-up position and the pin-down position alternatively to selectively remove the negative photoresist from the substrate.

### BACKGROUND OF THE INVENTION

### 1. Field of the Invention

The present invention relates to the technical field of semiconductor manufacturing, and more particularly to a method for removing patterned negative photoresist from a substrate.

### 2. Description of the Prior Art

As known in the art, a patterned photoresist layer is used as a mask during the high dose and high energy ion implantation step in the manufacturing process of semiconductors.

During the implantation step, the upper surface of the photoresist layer is transformed to a carbonized crust which contains arsenic, phosphorus and/or boron dopants. The thickness of the crust and the depth of the implanted species are directly related to the implantation energy and the types of dopants. Under the crust layer, the remainder of the photoresist layer is still present.

The next step is removing the crust and unaffected photoresist layer selective to the underlying material layer. However, in a subsequent resist removal step, it is difficult to completely remove the photoresist layer with the carbonized crust, especially for negative photoresists.

### SUMMARY OF THE INVENTION

One object of the present invention is to provide an improved method that can effectively remove the patterned negative photoresist from the semiconductor substrate.

One embodiment of the invention discloses a method for removing a patterned negative photoresist from a substrate, comprising the following steps: (a) placing the substrate having the patterned negative photoresist on lifting pins of a wafer chuck in a reaction chamber of a plasma reactor; (b) lowering the lifting pins to place the substrate in a pin-down position and concurrently heating the substrate to a first temperature not exceeding 100° C.; (c) raising the lifting pins to place the substrate in a pin-up position; (d) generating a plasma from a gas comprising NH₃; and (e) exposing the substrate to the plasma in said pin-up position and said pin-down position alternatively to selectively remove the negative photoresist from the substrate.

Another embodiment of the invention discloses a method for removing a patterned negative photoresist from a substrate, comprising the following steps: (a) subjecting the substrate having the patterned negative photoresist to a chemical oxide removal (COR) process; (b) placing the substrate having the patterned negative photoresist on lifting pins of a wafer chuck in a reaction chamber of a plasma reactor; (c) raising the lifting pins to place the substrate in a pin-up position to gradually heat the substrate to a first temperature not exceeding 100° C.; and (d) stripping the patterned negative photoresist by an oxygen-based plasma.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a schematic diagram of a plasma reactor according to an embodiment of the present invention.

FIG. 2 is an enlarged cross-sectional view of a substrate according to an embodiment of the invention.

FIG. 3 is a flow chart of a method for removing patterned negative photoresist from a substrate according to an embodiment of the invention.

FIG. 4 is a flow chart of a method for removing patterned negative photoresist from a substrate according to another embodiment of the present invention.

### DETAILED DESCRIPTION

In the following, the details will be described with reference to the drawings, the contents of which also form part of the description of the specification and are illustrated in the specific examples in which the embodiment can be practiced. The following examples have described sufficient details to enable those of ordinary skill in the art to practice this invention.

Of course, other embodiments may be adopted, or any structural, logical, and electrical changes may be made without departing from the embodiments described herein. Therefore, the following detailed description is not to be taken in a limiting sense, and the examples contained therein are to be defined by the appended claims.

The present invention relates to a method of removing patterned negative photoresist from a substrate. The patterned negative photoresist may refer to a negative photoresist processed through a high-dose implant (HDI) process or a wet chemical process.

Please refer to FIG. 1, which is a schematic diagram of a plasma reactor 200 according to an embodiment of the present invention. The exemplary plasma reactor 200 may be a downstream photoresist stripping device. As shown in FIG. 1, the plasma reactor 200 can be used to complete the photoresist stripping process after ion implantation. The plasma reactor 200 may comprise a reaction chamber 201 defined by a chamber wall 202, a chamber bottom 204, and a chamber top 206.

A semiconductor wafer support structure (or “wafer chuck”) 210 is disposed in the reaction chamber 201 near the chamber bottom 204. The wafer chuck 210 may comprise a plurality of lifting pins 212 for raising and lowering the semiconductor wafer (or “substrate”) 220 disposed on the wafer chuck 210 for processing.

The wafer chuck 210 also includes a heater plate 214 that is electrically operated. The plasma reactor 200 further includes an applicator tube 230 located above the chamber top 206. The applicator tube 230 communicates with the reaction chamber 201 through the showerhead 232. The processing gas supply line 234 is in fluid communication with the application tube 230 to supply the processing gas.

In the present invention, the preferred processing gas may comprise ammonia (NH₃) gas, oxygen gas, or a mixed gas of the above, but is not limited thereto. It should be understood by those skilled in the art that the processing gas supply line 234 may in fact supply any other type of processing gas.

In addition, the plasma reactor 200 can optionally be configured with a microwave energy source 240 connected to the applicator tube 230 to provide microwave energy to the processing gas in the applicator tube 230 thereby forming a downstream plasma gas, which flows through the showerhead 232, then enters the reaction chamber 201 and reaches the semiconductor wafer 220, such that the photoresist is exposed to the plasma gas and removed from the surface of the semiconductor wafer 220.

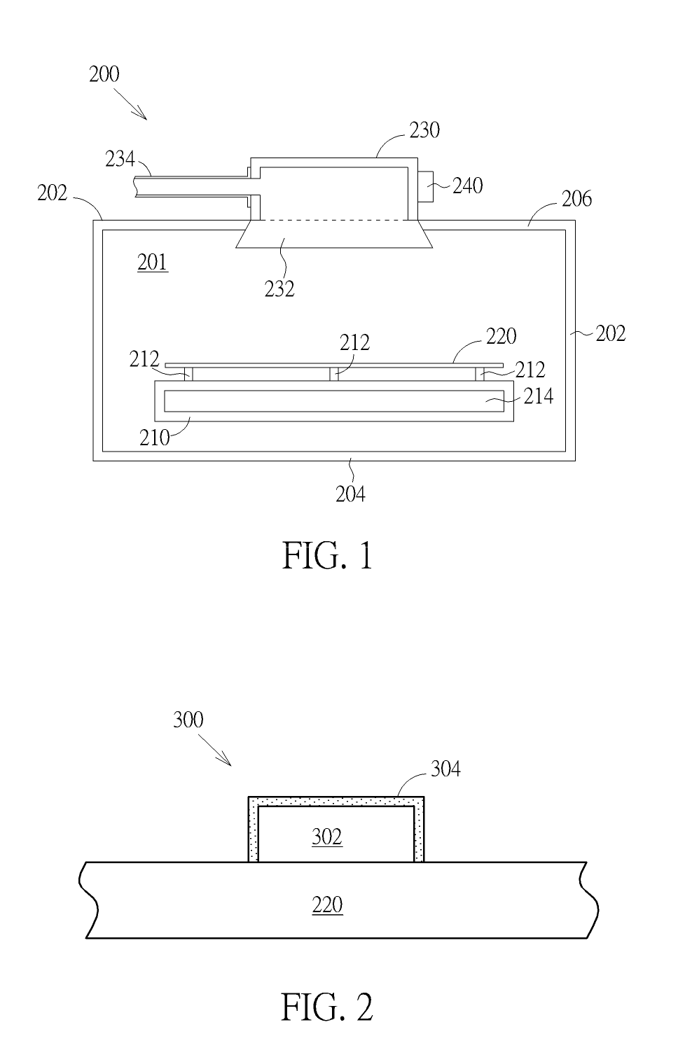

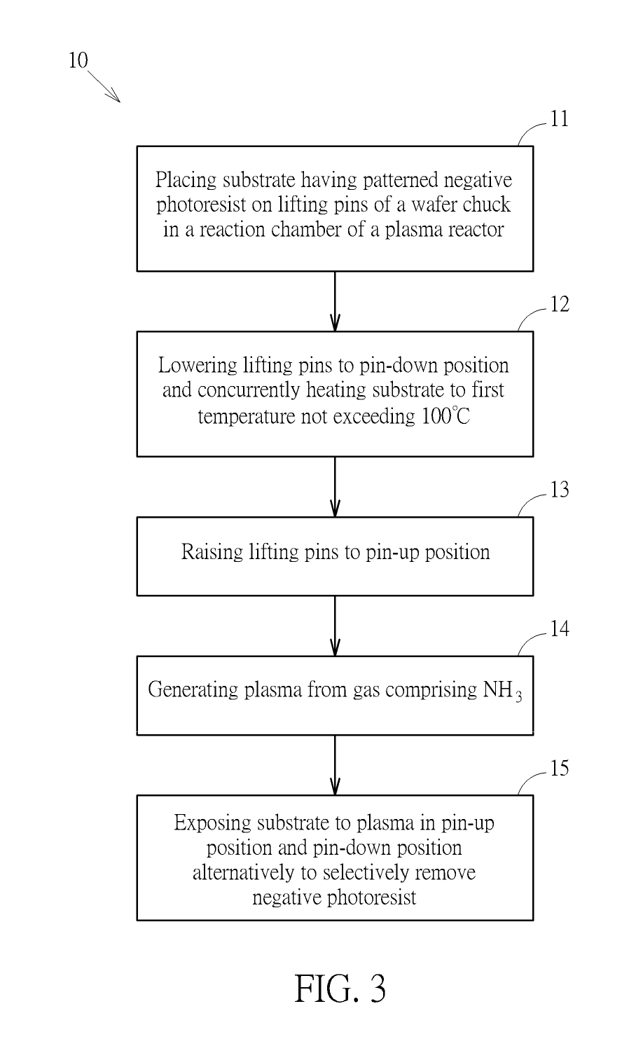

FIG. 2 is an enlarged cross-sectional view of a substrate 220 according to an embodiment of the present invention. As shown in FIG. 2, the substrate 220 may be a semiconductor substrate, such as a silicon substrate. In addition, a material layer may be formed on the substrate 220, but not limited thereto. A patterned negative photoresist 300 is disposed on the substrate 220. According to an embodiment of the present invention, the patterned negative photoresist 300 is subjected to a high-dose implant (HDI) process. According to an embodiment of the present invention, the patterned negative photoresist 300 includes a photoresist body layer 302 and a crust 304. According to another embodiment of the present invention, the patterned negative photoresist 300 may be a negative photoresist that has undergone a wet chemical process, such as a chemical oxide removal (COR) process. According to an embodiment of the present invention, for example, the patterned negative photoresist 300 may be a negative photoresist manufactured by JSR Corporation under the model number NSD253, but not limited thereto.

Please refer to FIG. 3, which is a flowchart of a method for removing patterned negative photoresist from a substrate according to an embodiment of the present invention. As shown in FIG. 3, the method 10 first performs Step 11 of placing the substrate 220 with the patterned negative photoresist 300 on the lifting pins 212 of the wafer chuck 210, where the wafer chuck 210 is located in the reaction chamber 201 of the plasma reactor 200. Then, proceeding to Step 12, the lifting pins 212 is lowered to place the substrate 220 in a pin-down position while heating the substrate 220 to a first temperature, wherein the first temperature does not exceed 100° C. For example, the first temperature is between 90 and 100° C. Then, Step 13 is performed to raise the lifting pins 212 so that the substrate 220 is located in a pin-up position. In Step 14, plasma is generated in the plasma reactor 200 using a gas containing ammonia gas. Then, in Step 15, the substrate 220 is brought into contact with the plasma at the pin-up position. The substrate 220 is alternately moved between the pin-up position and the pin-down position so that the patterned negative photoresist 300 can be completely removed from the surface of the substrate 220.

According to an embodiment of the present invention, in Step 15, the substrate 220 is alternately moved between the pin-up position and the pin-down position at a second temperature, wherein the second temperature is higher than the first temperature. For example, the second temperature is between 240 and 250° C. According to an embodiment of the invention, the gas in Step 14 is pure ammonia gas. According to an embodiment of the present invention, the gas in Step 14 further comprises oxygen.

According to an embodiment of the present invention, for example, in a case that a plasma composed of ammonia gas and oxygen gas is used, the gas flow rate of ammonia gas and oxygen gas is about 10000 sccm, the pressure is about 900 to 1000 mT, the reaction time is about 150 to 200 seconds, and no bias is used during the processing.

The present invention is characterized in that by contacting the substrate 220 with the plasma at the pin-up position of the lifting pins, hardening of the crust 304 due to the rapid temperature rise of the substrate 220 can be prevented. As a result, the crust 304 of the negative photoresist 300 can be easily removed with ammonia gas plasma at a temperature near 100° C. Subsequently, the remaining photoresist body layer 302 can be removed by alternately moving the substrate between the pin-up position and the pin-down position at high temperature with plasma.

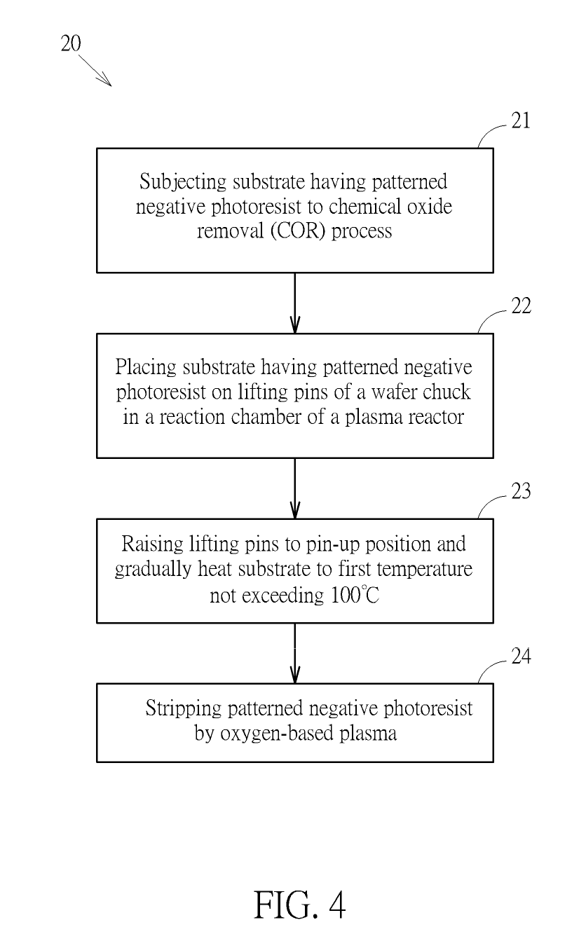

Please refer to FIG. 4, which is a flow chart of a method for removing patterned negative photoresist from a substrate according to another embodiment of the present invention. As shown in FIG. 4, the method 20 first proceeds to Step 21 to perform a chemical oxide removal (COR) process on the substrate 220 having the patterned negative photoresist 300. Then, proceeding to Step 22, the substrate 220 having the patterned negative photoresist 300 is placed on the lifting pins 212 of the wafer chuck 210, where the wafer chuck 210 is located in the reaction chamber 201 of the plasma reactor 200. Then, proceeding to Step 23, the lifting pins 212 are raised to position the substrate 220 at a pin-up position while gradually heating the substrate 220 to a first temperature, wherein the first temperature does not exceed 100° C. For example, the first temperature is between 90 and 100° C. Next, Step 24 is performed to remove the patterned negative photoresist 300 by oxygen plasma, such as by downstream plasma. Step 24 is carried out at a second temperature, wherein the second temperature does not exceed 110° C.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A method for removing a patterned negative photoresist from a substrate, comprising the following steps:
(a) placing the substrate having the patterned negative photoresist on lifting pins of a wafer chuck in a reaction chamber of a plasma reactor;
(b) lowering the lifting pins to place the substrate in a pin-down position and concurrently heating the substrate to a first temperature not exceeding 100° C.;
(c) raising the lifting pins to place the substrate in a pin-up position;
(d) generating a plasma from a gas comprising NH₃; and
(e) exposing the substrate to the plasma in said pin-up position and said pin-down position alternatively to selectively remove the negative photoresist from the substrate.

2. The method according to claim 1, wherein the first temperature ranges between 90˜100° C.

3. The method according to claim 1, wherein Step (e) is performed at a second temperature, wherein the second temperature is higher than the first temperature.

4. The method according to claim 3, wherein the second temperature ranges between 240˜250° C.

5. The method according to claim 1, wherein the gas in Step (d) is pure NH₃.

6. The method according to claim 1, wherein the gas in Step (d) further comprises O₂.

7. A method for removing a patterned negative photoresist from a substrate, comprising the following steps:
(a) subjecting the substrate having the patterned negative photoresist to a chemical oxide removal (COR) process;
(b) placing the substrate having the patterned negative photoresist on lifting pins of a wafer chuck in a reaction chamber of a plasma reactor;
(c) raising the lifting pins to place the substrate in a pin-up position to gradually heat the substrate to a first temperature not exceeding 100° C.; and
(d) stripping the patterned negative photoresist by an oxygen-based plasma.

8. The method according to claim 7, wherein the first temperature ranges between 90˜100° C.

9. The method according to claim 7, wherein the Step (d) is performed at a second temperature not exceeding 110° C.

10. The method according to claim 7, wherein the oxygen-based plasma comprises downstream plasma.
